(19) United States
(12) Patent Application Publication
(10) Pub. No.: US 2016/0307891 A1
(43) Pub. Date: Oct. 20, 2016

(54) Semiconductor Device Comprising a Transistor Including a Body Contact Portion and Method for Manufacturing the Semiconductor Device

(71) Applicant: Infineon Technologies AG, Neubiberg (DE)

(72) Inventors: Andreas Meiser, Sauerlach (DE); Till Schloesser, Munchen (DE)

(21) Appl. No.: 15/096,629

(22) Filed: Apr. 12, 2016

(30) Foreign Application Priority Data
Apr. 14, 2015 (DE) 102015105665.8

(51) Int. Cl. H01L 27/088; H01L 29/78; H01L 29/10; H01L 29/40; H01L 29/417

(52) U.S. Cl. CPC H01L 27/088; H01L 29/402; H01L 29/41775; H01L 29/1095; H01L 29/7823; H01L 29/7825; H01L 29/4175

(57) ABSTRACT

A semiconductor device comprises a transistor in a semiconductor body having a main surface. The transistor comprises a source region, a drain region, a body region, a drift zone, and a gate electrode at the body region. The body region and the drift zone are disposed along a first direction between the source region and the drain region, the first direction being parallel to the main surface. The gate electrode is disposed in a trench extending in the first direction. The semiconductor device further comprises a source contact electrically connected to the source region and to a source terminal. The source contact is disposed in a source contact opening in the main surface. The semiconductor device further comprises a body contact portion electrically connected to the source terminal and to the body region. The body contact portion vertically overlaps with the source region.

### BACKGROUND

Power transistors commonly employed in automotive and industrial electronics should have a low on-state resistance (Rₒₙ·A), while securing a high voltage blocking capability. For example, a MOS (“metal oxide semiconductor” power transistor should be capable, depending upon application requirements, to block to drain to source voltages V_{ds} of some tens to some hundreds or thousands volts. MOS power transistors typically conduct very large currents which may be up to some hundreds of amperes at typical gate-source voltages of about 2 to 20 V.

A concept for transistors having a further improved Rₒₙ·A characteristic refers to lateral power FinFET (“field effect transistors comprising a fin”). Lateral power FinFETs utilize more bulk silicon for reducing Rₒₙ so that Rₒₙ is comparable to that of a vertical trench MOSFET. In transistors comprising a lateral field plate, the doping concentration of the drift zone may be increased, due to the compensation action of the field plate.

It is an object of the present invention to provide a semiconductor device comprising a transistor having improved properties.

### SUMMARY

According to an embodiment, a semiconductor device comprises a transistor in a semiconductor body having a main surface. The transistor comprises a source region, a drain region, a body region, a drift zone, and a gate electrode at the body region. The body region and the drift zone are disposed along a first direction between the source region and the drain region. The first direction is parallel to the main surface. The gate electrode is disposed in trenches extending in the first direction. The transistor further comprises a source contact electrically connected to the source region and to a source terminal. The source contact is disposed in a source contact opening in the main surface. The transistor comprises a body contact portion electrically connected to the source terminal and to the body region, the body contact portion vertically overlapping with the source region.

According to a further embodiment, a semiconductor device comprises an array of transistors in a semiconductor body having a main surface. Each of the transistors comprises a source region, a drain region, a body region, a drift zone, and a gate electrode at the body region. The body region and the drift zone are disposed along a first direction between the source region and the drain region. The first direction is parallel to the main surface. The gate electrode is disposed in trenches extending in the first direction. The semiconductor device further comprises a source contact electrically connected to the source region and to a source terminal, and a body contact portion electrically connected to the source contact and to the body region, the body contact portion being disposed at a sidewall of the source contact.

According to an embodiment, a method of manufacturing a semiconductor device comprising an array of transistors in a semiconductor body having a main surface comprises forming source regions, forming drain regions, forming body regions, forming drift zones, and forming gate electrodes at the body regions, respectively. The body regions and corresponding drift zones are disposed along a first direction between the source regions and the drain regions, respectively, the first direction being parallel to the main surface. The gate electrode is formed in trenches extending in the first direction. The method further comprises forming source contacts electrically connected to the source region and to a source terminal. The source contacts are formed in a source contact opening in the main surface. The method comprises forming body contact portions electrically connected to the source terminal and to the body region, the body contact portion being formed so as to vertically overlap with the source region.

According to an embodiment, a semiconductor device comprises an array of transistors in a semiconductor body having a main surface. Each of the transistors comprises a source region, a drain region, a body region, a drift zone, and a gate electrode at the body region. The body region and the drift zone are disposed along a first direction between the source region and the drain region, the first direction being parallel to the main surface. The gate electrode is disposed in trenches extending in the first direction. Each of the transistors further comprises a first source contact electrically connected to the source region and to a source terminal, a second source contact disposed in a second source contact opening in the semiconductor body, and a body contact portion electrically connected to the second source contact and to the body region. The body contact portion is disposed at a sidewall of the second source contact opening.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1E show various views of a semiconductor device according to an embodiment.

FIGS. 2A to 2C show views of a semiconductor device according to a further embodiment.

FIGS. 3A to 3C show views of semiconductor devices according to further embodiments.

FIGS. 4A to 4C show views of a semiconductor device according to a further embodiment.

FIG. 5 summarizes a method for manufacturing a semiconductor device according to an embodiment.

FIGS. 6A to 6C illustrate various views of a semiconductor device when performing processes for manufacturing a semiconductor device according to an embodiment.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

As employed in this specification, the terms “coupled” and/or “electrically coupled” are not meant to mean that the elements must be directly coupled together—intervening elements may be provided between the “coupled” or “electrically coupled” elements. The term “electrically connected” intends to describe a low-ohmic electric connection between the elements electrically connected together.

The present specification refers to a “first” and a “second” conductivity type of dopants, semiconductor portions are doped with. The first conductivity type may be p type and the second conductivity type may be n type or vice versa. As is generally known, depending on the doping type or the polarity of the source and drain regions, insulated gate field effect transistors (IGFETs) such as metal oxide semiconductor field effect transistors (MOSFETs) may be n-channel or p-channel MOSFETs. For example, in an n-channel MOSFET, the source and the drain region are doped with n-type dopants. In a p-channel MOSFET, the source and the drain region are doped with p-type dopants. As is to be clearly understood, within the context of the present specification, the doping types may be reversed. If a specific current path is described using directional language, this description is to be merely understood to indicate the path and not the polarity of the current flow, i.e. whether the current flows from source to drain or vice versa. The Figures may include polarity-sensitive components, e.g. diodes. As is to be clearly understood, the specific arrangement of these polarity-sensitive components is given as an example and may be inverted in order to achieve the described functionality, depending whether the first conductivity type means n-type or p-type.

The Figures and the description illustrate relative doping concentrations by indicating “−” or “+” next to the doping type “n” or “p”. For example, “n-” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations. In the Figures and the description, for the sake of a better comprehension, often the doped portions are designated as being “p” or “n”-doped. As is clearly to be understood, this designation is by no means intended to be limiting. The doping type can be arbitrary as long as the described functionality is achieved. Further, in all embodiments, the doping types can be reversed.

The terms “lateral” and “horizontal” as used in this specification intends to describe an orientation parallel to a first surface of a semiconductor substrate or semiconductor body. This can be for instance the surface of a wafer or a die.

The term “vertical” as used in this specification intends to describe an orientation which is arranged perpendicular to the first surface of the semiconductor substrate or semiconductor body.

The terms “wafer”, “substrate”, “semiconductor substrate” or “semiconductor body” used in the following description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide. According to other embodiments, silicon carbide (SiC) or gallium nitride (GaN) may form the semiconductor substrate material.

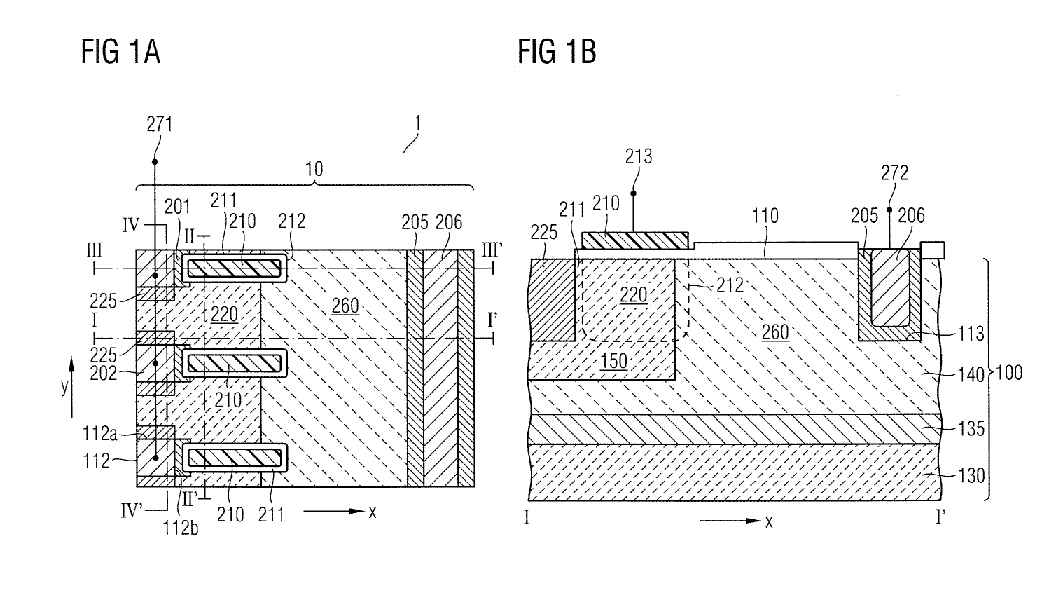

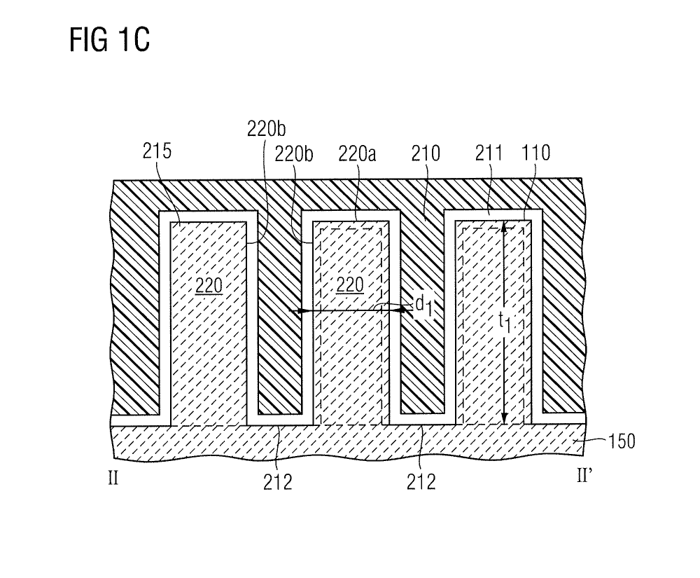

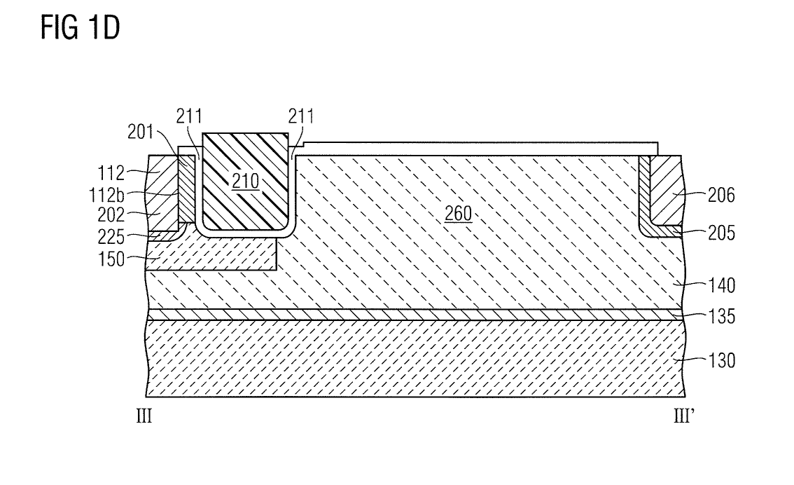

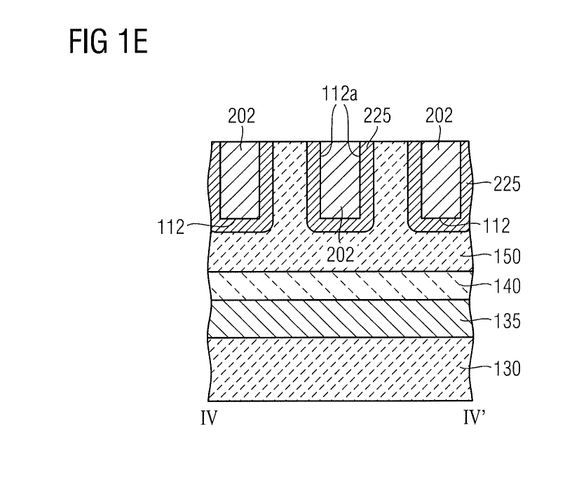

FIG. 1A shows a horizontal cross-sectional view of a semiconductor device according to an embodiment. As will be explained in the following, the semiconductor device comprises a transistor 10 in a semiconductor body having a main surface. The transistor 10 comprises a source region 201, a drain region 205, a body region 220, a drift zone 260, and a gate electrode 210 at the body region 220. The body region 220 and the drift zone 260 are disposed along a first direction (e.g. the x direction) between the source region 201 and the drain region 205. The first direction is parallel to the main surface. The gate electrode 210 is disposed in trenches 212 extending in the first direction. The transistor further comprises a source contact 202 that is electrically connected to the source region 201 and to a source terminal 271. The transistor further comprises a body contact portion 225 electrically connected to the source contact 202 and to the body region 220. The body contact portion 225 may be disposed at the main surface. As will be discussed with reference to FIGS. 1B and 1D, the body contact portion 225 vertically overlaps with the source region 201. Within the context of the present specification, the wording “vertically overlaps with” is intended to mean that the respective portions or regions may extend in the same depth. In more detail, there may be a vertical extension of the semiconductor body at which the respective portions or regions may be present. To be more specific, the starting points of the respective portions or regions do not need to coincide. Further, the end points of the respective portions or regions do not need to coincide.

FIG. 1B shows a cross-sectional view between I and I′, as is also illustrated in FIG. 1A. The cross-sectional view of FIG. 1B is taken so as to be disposed between adjacent gate trenches 212. As will be further illustrated with reference to FIG. 1C, a plurality of gate trenches 212, each extending along the first direction, pattern the body region 220 into ridges. Accordingly, in the cross-sectional view of FIG. 1B, the gate trenches 212 are disposed before or behind the depicted plane of the drawing. According to an embodiment, a gate electrode 210 may be disposed in each of the gate trenches 212, a gate dielectric 211 such as silicon oxide or silicon nitride being disposed between the gate electrode 210 and the adjacent body region 220. According to further implementations, a material different from a conductive material, e.g. an insulating material, may be disposed in some of the gate trenches 212. Alternatively, the conductive material in some of the gate trenches 212 may be connected to a terminal that is different from the gate terminal 213. The body contact portions 225 vertically overlap with the gate trenches 212. For example, the body contact portions 225 may extend from the main surface 110 to approximately the entire depth of the gate trenches or less. According to embodiments, the body contact portions 225 may extend to more than 0.5× the depth of the gate trenches 212, e.g. to more than 0.6 or even more than 0.8× the depth of the gate trenches 212.

The semiconductor body or semiconductor substrate 100 may comprise a first (bottom) layer 130 of a first conductivity type (e.g. p-type) and an epitaxially grown second layer 140 of a second conductivity type different from the first conductivity type formed over the first layer 130. A further buried layer 135 of the second conductivity type may be disposed between the first layer 130 of the first conductivity type and the second layer 140 of the second conductivity type. The buried layer 135 may be doped at a higher doping concentration than the second layer 140 of the second conductivity type. The components of the field effect transistor 10 may be formed in a well 150 of the first conductivity type, e.g. p-type. The first well 150 may be formed in the second layer 140 of the second conductivity type. The drift zone 260 is formed in the second layer 140 of the second conductivity type.

According to the embodiment illustrated in FIG. 1B, the drain region 205 is formed in a semiconductor portion at a sidewall and at a bottom side of a drain contact groove 113 that is formed in the main surface 110 of the semiconductor body 100. A conductive material is disposed in the drain contact groove 113 to form the drain contact. The drain contact 206 may be electrically coupled to a drain terminal 272.

According to the embodiment shown in FIGS. 1A and 1B, the source contact 202 may be disposed in a source contact opening 112 in the main surface 110. According to the embodiment, the body contact portion 225 may vertically extend along at least a portion of the source contact opening 112. To be more specific, the body contact portion 225 is formed in the semiconductor body 100 and extends along a first sidewall 112a of the source contact opening in the depth direction. The first sidewall 112a extends in the first direction. Moreover, the source region 201 may vertically extend along the source contact opening 112. In more detail, the source region 201 extends along a second sidewall 112b of the source contact opening 112 in the depth direction. The second sidewall 112b extends in the second direction which may be perpendicular to the first direction. As a result, the body contact portion 225 and the source region 201 vertically overlap. According to the embodiment of FIGS. 1A to 1E, the source contact opening 112 and the source region 201 are arranged along the first direction. Moreover, the source contact opening 112 and the body contact region 225 are arranged along a second direction which is different from the first direction.

FIG. 1C shows a cross-sectional view between II and II′, as is also illustrated in FIG. 1A. The cross-sectional view of FIG. 1C is taken so as to intersect a plurality of gate trenches 212. As is illustrated, separated portions of semiconductor material of the well portion 150 of the second conductivity type forming the single ridges or fins may be patterned by adjacent gate trenches 212. The ridges comprise a top surface 220a and sidewalls 220b. A gate dielectric layer 211 is disposed adjacent to the sidewalls 220b and the top surface 220a of each of the ridges. Further, a conductive material is filled in the trenches 212 between adjacent ridges to form the gate electrode 210. As a result, the body region 220 has the shape of a ridge extending in the first direction or the shape of a fin.

The sidewalls 220b may extend perpendicularly or at an angle of more than 75° with respect to the main surface 110. The gate electrode 210 may be disposed adjacent to at least two sides of the ridge.

When the transistor is switched on, e.g. by applying a suitable voltage to the gate electrode 210, a conductive inversion layer 215 (conductive channel) is formed at the boundary between the body region 220 and the gate dielectric layer 211. Accordingly, the transistor is in a conducting state from the source region 201 to the drain region 205. In case of switching off, no conductive inversion layer is formed and the transistor is in a non-conducting state.

According to an embodiment, the conductive channel regions 215 formed at opposing sidewalls 220b of a ridge do not merge with each other so that the body region 220 may not be fully depleted and may be connected to the source region and to the body contact region 225. For example, the width of the first trenches may be approximately 50 to 1000 nm, for example 40 to 400 nm, more specifically 100 to 300 nm along the main surface 110 of the semiconductor body 100. Further, the distance between adjacent gate trenches 212 that corresponds to the width d₁ of the ridges may be larger than 200 nm, e.g. 200 to 1000 nm, for example, 400 to 600 nm.

FIG. 1D shows a cross-sectional view of the semiconductor device between III and III′ as is also illustrated in FIG. 1A. The cross-sectional view of FIG. 1D extends along the first direction and intersects the transistor along the gate electrode 210. As is particularly illustrated in FIG. 1D, the source region 201 is disposed between the source contact opening 112 and the gate electrode 210. Moreover, the body contact region 225 may be disposed adjacent to a bottom side of the source contact opening 112. In the cross-sectional view of FIG. 1D, the body region is disposed before and behind the depicted plane of the drawing.

According to the embodiment illustrated in FIGS. 1A to 1d, the source contact openings 112 are disposed adjacent to gate trenches 212. The source contact openings 112, the source regions 201 and the gate electrodes 210 may be arranged along the first direction.

FIG. 1E shows a cross-sectional view between IV and IV′, as is also illustrated in FIG. 1A. The cross-sectional view of FIG. 1E is taken along the second direction so as to intersect a plurality of source contact openings 112. As is illustrated, the body contact portion 225 is disposed adjacent to a first sidewall 112a of the source contact opening 112. Further, the body contact portion 225 is disposed adjacent to a bottom side of the source contact openings 112. The body contact portion 225 extends along the first sidewall 112a of the source contact opening 112 to the bottom side and along the bottom side of the source contact opening 112. The body contact portion 225 may extend to the main surface 110 of the semiconductor body 100.

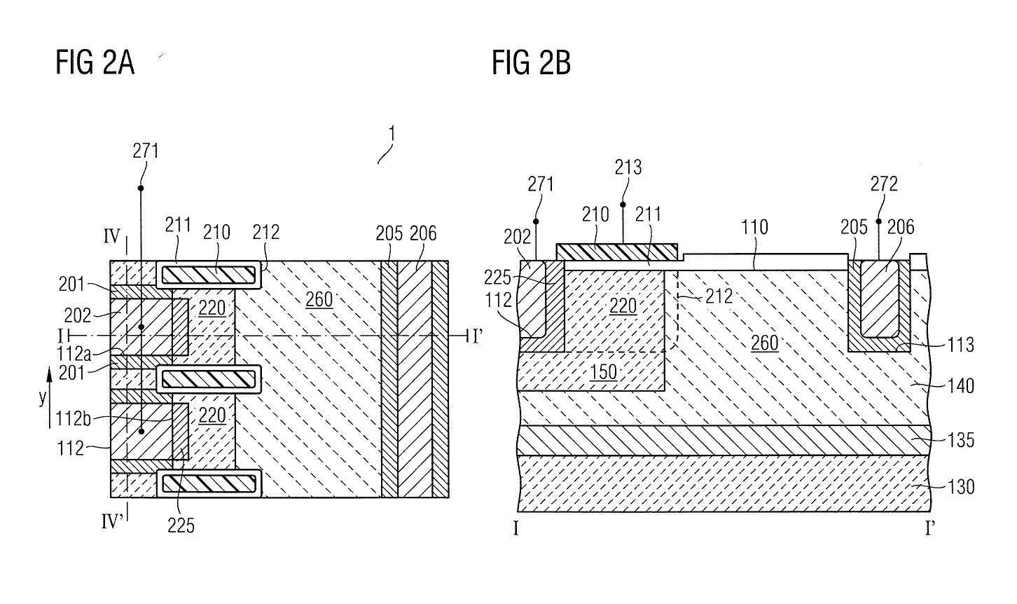

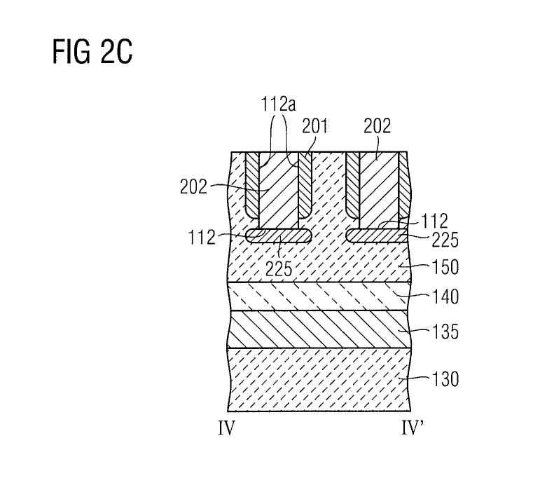

FIG. 2A shows a semiconductor device according to a further embodiment. In FIG. 2A, the same components as those illustrated in FIG. 1A are designated by the same reference numerals. Different from the embodiment illustrated in FIG. 1A, the source contact opening 112 and the body contact portion 225 are arranged along the first direction. Further, the source contact opening 112 and the source regions 201 are arranged along the second direction.

According to all embodiments described herein, due to the feature that the body contact portion 225 vertically overlaps with the source region 201, and additionally the feature that the body contact portion 225 is electrically connected to the source contact, the suppression of the parasitic bipolar transistor may be improved. In more detail, holes may be efficiently removed from the body region, thereby preventing detrimental effects such as a snap-back effect. This results in an improved safe-operating area (SOA) that corresponds to a region in the I-V-characteristic in which the semiconductor device may be safely operated. According to the embodiment shown in FIG. 2A, these effects may be further improved since a distance between the drift zone 260 and the body contact portion 225 is further reduced. According to a different interpretation, the body contact portion 225 may be disposed at a sidewall of the source contact. In particular, the source contact 202 may extend into the semiconductor body 100.

According to the embodiment of FIG. 2A, the source regions 201 are disposed adjacent to the first sidewalls 112a of the source contact openings 112, and the body contact portions 225 are disposed adjacent to the second sidewalls 112b of the source contact openings 112. The first sidewalls 112a extend in the first direction, and the second sidewalls 112b extend in the second direction which may be perpendicular to the first direction.

The gate trenches 212 are disposed between adjacent source regions 201. The source regions 201 assigned to adjacent source contact openings 112 are arranged in a manner that they do not contact each other. The gate trenches 212 are disposed at a position corresponding to half the distance between adjacent source contact openings 112. The gate electrodes 210 and, consequently the gate trenches 212 may extend along the first direction so as to extend along the source contact openings.

FIG. 2B shows a cross-sectional view between I and I′, as is also illustrated in FIG. 2A. The cross-sectional view of FIG. 2B is taken so as to cut through the body region 220 between adjacent gate trenches 212. In FIG. 2B, the gate trenches 212 are disposed before and behind the depicted plane of the drawing. As is illustrated, the source contact 202, the body contact portion 225 and the body region 220 are arranged along the first direction.

The further components of FIG. 2B are similar to those of FIG. 1B. FIG. 2C shows a cross-sectional view between IV and IV′, as is also illustrated in FIG. 2A. The cross-sectional view of FIG. 2C is taken so as to intersect the source contact openings 112 along the second direction. As is shown, the source regions 201 are formed at first sidewalls 112a of the source contact openings 112. The body contact portion 225 is disposed at a bottom side of the source contact openings and at second sidewalls 112b of the source contact openings 112. In a similar manner as has been discussed above with reference to FIGS. 1A to 1D, the body contact portion 225 vertically overlaps with the source region. According to a different interpretation, the body contact portion is disposed at a sidewall of the source contact. For example, the source contact extends into the semiconductor body 100.

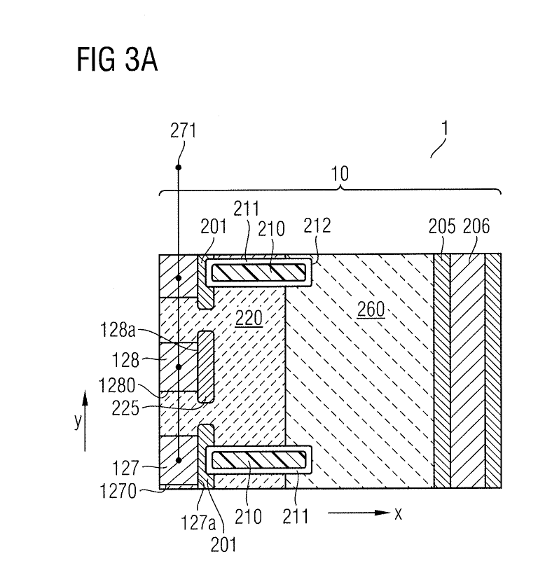

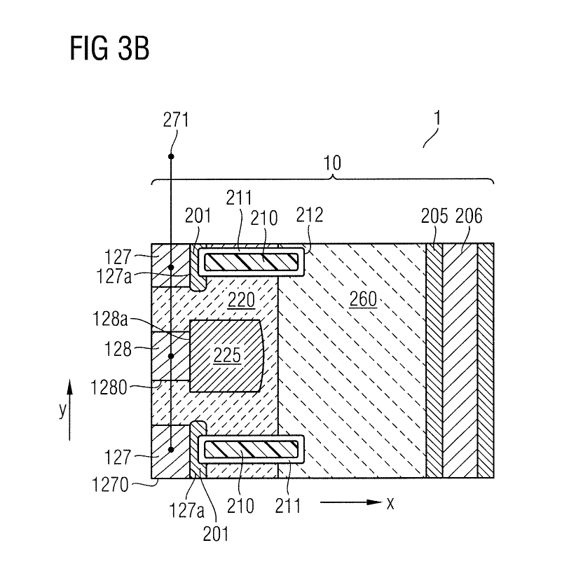

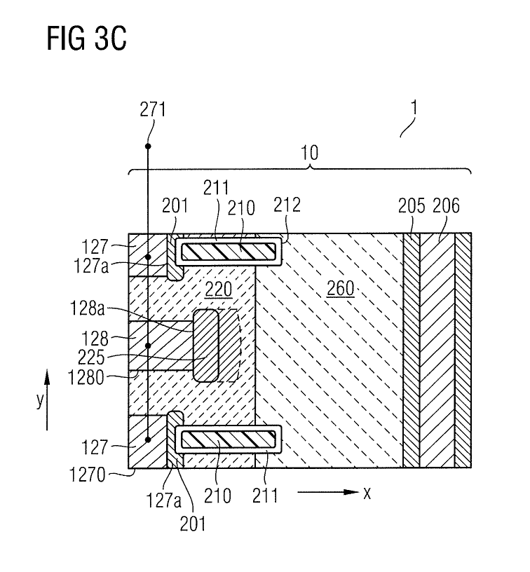

FIG. 3A shows a horizontal cross-sectional view of a semiconductor device according to a further embodiment. Differing from the embodiment illustrated in FIG. 1A, different sidewall dopings are disposed adjacent to separated contacts which are electrically connected to a source terminal 271, respectively. In more detail, a semiconductor device 1 comprises an array of transistors 10 in a semiconductor body having a main surface 110. Each of the transistors comprises a source region 201, a drain region 205, a body region 220, a drift zone 260, and a gate electrode 210 at the body region 220. The body region 220 and the drift zone 260 are disposed along a first direction between the source region 201 and the drain region 205, the first direction being parallel to the main surface 110. The gate electrode 210 is disposed in trenches 212 extending in the first direction. Each of the transistors further comprises a first source contact 127 electrically connected to the source region 201 and to a source terminal 271. Each of the transistors additionally comprises a second source contact 128 disposed in a second source contact opening 1280 in the semiconductor body, and a body contact portion 225 which is electrically connected to the second source contact 128 and to the body region 220. The body contact portion 225 is disposed at a sidewall of the second source contact opening 1280.

According to an embodiment, the first source contact 127 and the second source contact 128 may be alternatingly disposed. The first source contact 127 may be disposed in a first source contact opening 1270 in the semiconductor body. For example, the first source contact openings and the second source contact openings may be formed by processing steps. For example, the first source contact openings and the second source contact openings 1280 may be identical in shape. The source region 201 may be disposed at a sidewall 127a of the first source contact opening 1270. For example, the source region 201 and the body contact portion 225 may be disposed at sidewalls 127a, 128a that extend along a second direction perpendicular to the first direction. The further components of FIG. 3A are similar to those of FIG. 1A. In particular, cross-sectional views may be similar to those shown in FIGS. 1B to 1D.

FIG. 3B shows a horizontal cross-sectional view of a semiconductor device according to a further embodiment. Differing from the embodiment shown in FIG. 3A, the dopants for forming the body contact portion 225 are out-diffused towards the drain region 205. As a result, a distance between the body contact portion 225 and the drain region 205 is smaller than a distance between the source region 201 and the drain region 205. The shape of the second source contacts 128 may be identical with a shape of the first source contacts 127. The further components of the embodiment shown in FIG. 3B are similar to those shown in FIG. 3A.

FIG. 3C shows a horizontal cross-sectional view of a semiconductor device according to still a further embodiment. Differing from the embodiment shown in FIG. 3B, the second source contact 128 differs in shape from the first source contact 127. In particular, the second source contact 128 has a larger width measured in the first direction than the first source contact 127. As a result, a distance between the body contact portion 225 and the drain region 205 is decreased. In particular, a distance between the body contact portion 225 and the drain region 205 is smaller than a distance between the source region 201 and the drain region 205. As is indicated by dotted lines, a width of the body contact portion 225 measured along the first direction may be larger than a width of the source region. By way of example, an out-diffusion process may be carried out so as to enlarge the width of the body contact portion 225. The further components of the semiconductor device shown in FIG. 3C are similar to those illustrated herein before.

According to the configuration shown in FIGS. 3A to 3C majority carriers, e.g. holes may be more efficiently removed from the body region, resulting in a further improved safe-operating area.

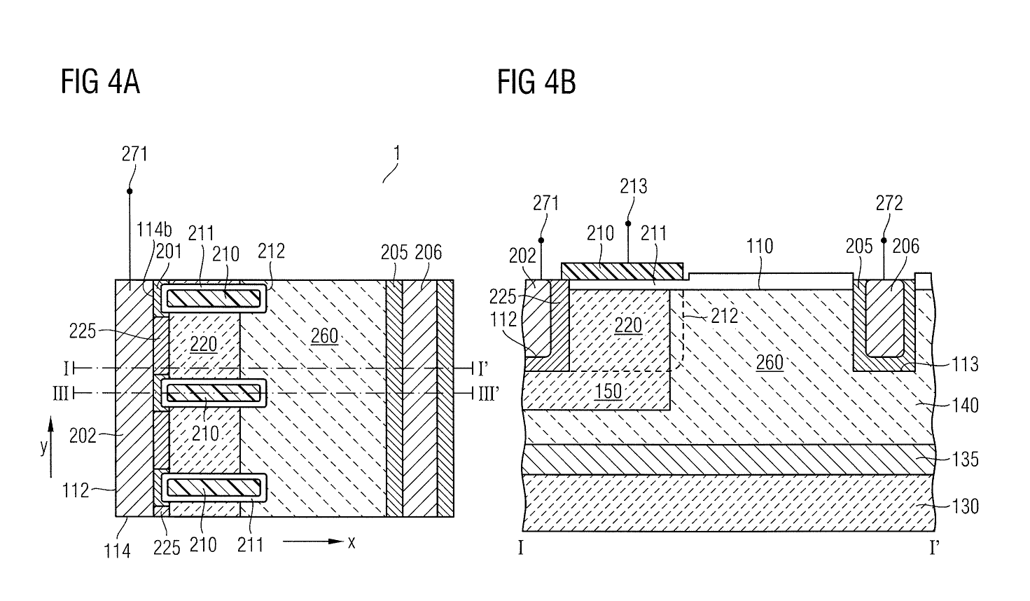

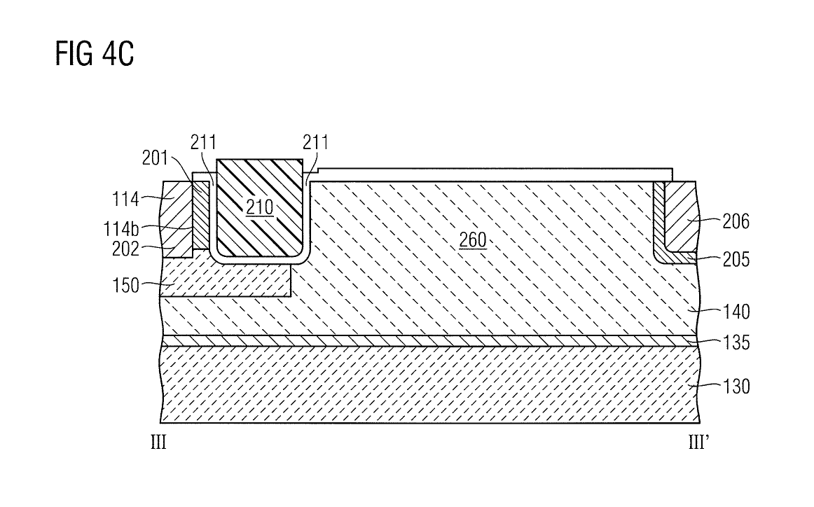

FIGS. 4A to 4C illustrate various views of a semiconductor device according to a further embodiment. Differing from the embodiment illustrated in FIGS. 1A and 2A, according to the embodiment shown in FIG. 4A, the source contact 202 is disposed in a source contact groove 114 extending along the second direction, e.g. the Y-direction. According to the embodiment of FIG. 4A, sections of a semiconductor material adjacent to a sidewall 114b of the source contact groove 114 are differently doped so as to define the body contact portions 225 and the source regions 201, respectively. For example, this may be accomplished by masking the different sections of the sidewall 114b when performing the respective doping processes. The gate trenches 212 and, consequently, the gate electrodes 210 are disposed so as to be adjacent to the source region 201, whereas the body contact portion 225 is disposed at a position between adjacent gate trenches 212.

FIG. 4B shows a cross-sectional view that is taken between I and I′, as is also illustrated in FIG. 4A. The cross-sectional view is taken so as to be disposed between adjacent gate trenches 212. The position of the gate trenches 212 is before and behind the depicted plane of the drawing and indicated by dotted lines. The body contact portion 225 is disposed between the source contact 202 and the body region 220 along the first direction. The further components are similar to those illustrated in FIGS. 2B and 1B.

FIG. 4C shows a cross-sectional view of the semiconductor device that is taken between III and III′, as is also illustrated in FIG. 4A. The cross-sectional view of FIG. 4C intersects the gate electrode 210. As is illustrated, the source region 201 extends approximately to the bottom side of the source contact groove 114. In a similar manner as has been discussed above with reference to FIGS. 1A to 1D, according to the embodiment of FIGS. 4A to 4C, the body contact portion 225 vertically overlaps with the source region. According to a different interpretation, the body contact portion is disposed at a sidewall of the source contact. For example, the source contact extends into the semiconductor body 100.

As has been illustrated with reference to FIGS. 1A to 4C, the transistor comprises a body contact portion 225 that may be disposed at a sidewall of a source contact. For example, the body contact portion 225 may extend to at least the depth of the source contact opening 112, the second source contact opening 1280 or source contact groove 114. According to further embodiments, the body contact portion 225 may extend to at least half the depth of the source contact opening 112, the second source contact opening 1280 or the source contact groove 114. For example, the body contact portion 225 may extend from the main surface 110. According to embodiments, as is specifically illustrated in FIGS. 1E, 2C, 2B, 4B, the body contact portion may also be disposed below a bottom side of the source contact opening 112, the second source contact opening 1280 or the source contact groove 114. As a result, a parasitic bipolar transistor may be deteriorated or suppressed in an improved manner. To be more specific, holes may be more effectively prevented from flowing across the body region 220. All the embodiments show a drift zone 260. As is readily to be understood, in addition, field plates may be disposed at the drift zone 260. For example, the field plates may be implemented as a planar field plate or the field plates may be disposed in field plate trenches extending along the first direction in the main surface. As a result, the drift zone 260 may as well be patterned into ridges. Moreover, the drift zone 260 may be further modified, e.g. may be implemented by a p-n superjunction layer stack.

The semiconductor device 1 comprises a plurality of single transistors 10 which may be connected in parallel. The pattern of the single transistors 10 may be repeated and mirrored along the first and the second directions. According to the embodiment of FIGS. 1A to 2C, the source contact openings 112 of parallel transistors may be spatially separated from each other. The source contacts 202 may be connected by a common line to a source terminal 271.

According to the embodiments illustrated in FIGS. 3A to 3C, first and second source contacts 127, 128 may be connected by a common line to a source terminal 271. A source region 201 may be disposed adjacent to first source contacts 127, and body contact portions 225 may be disposed adjacent to second source contacts 128. A distance between adjacent gate trenches 212 may correspond to the twofold distance between adjacent first and second source contacts 127, 128. In other words, the gate trenches 212 may be disposed at the pitch of the first gate contacts 127.

According to the embodiment illustrated in FIGS. 4A to 4C, the source regions 201 of parallel transistors may be connected by a common source contact 202 that is disposed in the source contact groove 114.

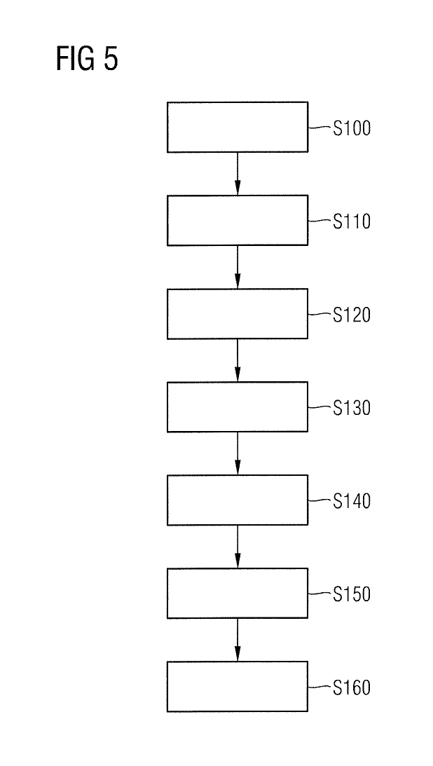

FIG. 5 summarizes a method of manufacturing a semiconductor device. A method of manufacturing a semiconductor device comprising an array of transistors in a semiconductor body having a main surface comprises forming source regions (S100), forming drain regions (S110), forming body regions (S120), forming drift zones (S130), and forming gate electrodes (S140) at the body regions, respectively. The body regions and corresponding drift zones are disposed along a first direction between the source regions and the drain regions, respectively, the first direction being parallel to the main surface. The body region has the shape of a ridge extending along the first direction. The method further comprises forming source contacts (S150) electrically connected to the source region and to a source terminal, and forming body contact portions (S160) electrically connected to the source contact and to the body region. The body contact portion are formed at the main surface. The succession of the single processes may be selected in accordance with the requirements of the manufacturing process. For example, the gate electrodes may be formed before forming the source regions, and further changes of the processing sequence may be made. Moreover, some of the processing steps may be performed by joint processing steps. For example, doping processes for different components may be simultaneously performed.

According to an embodiment, forming the source contacts may comprise forming a source contact groove and forming a conductive material in the source contact groove.

According to a further embodiment, forming the source contact openings may comprise forming first and second source contact openings.

The method may further comprise performing tilted ion implantation processes so as to define the source regions and the body contact portions.

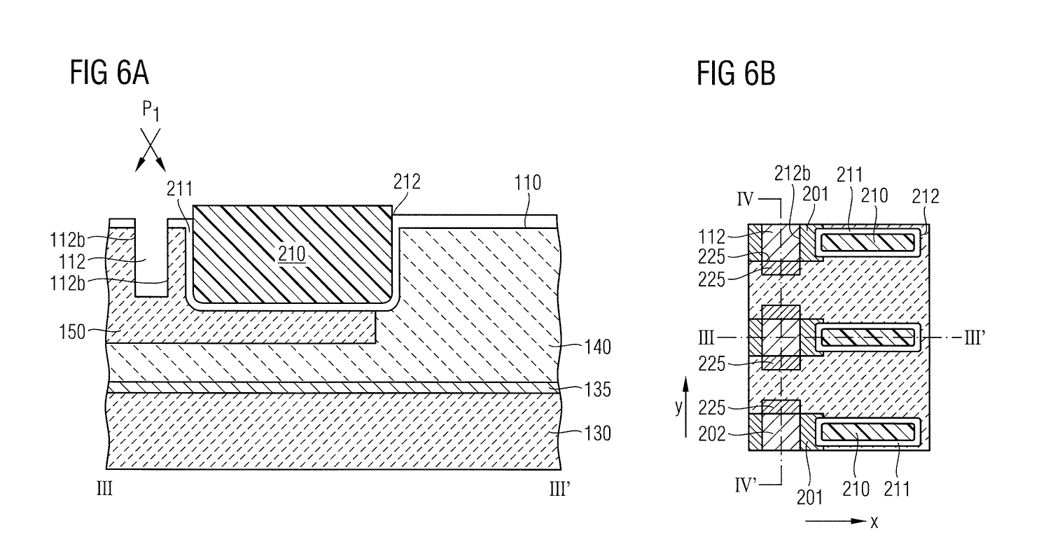

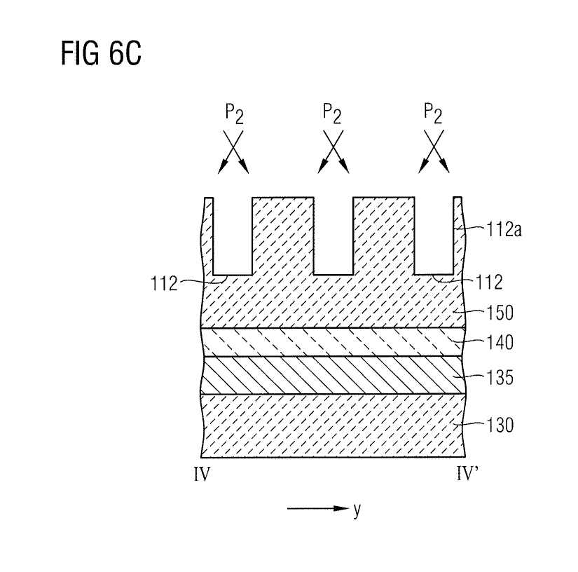

FIGS. 6A to 6C illustrate an example of a semiconductor substrate when performing a method of manufacturing the semiconductor device of FIGS. 1A to 1E. By way of example, first, the gate trenches 212 may be formed. The gate trenches 212 may extend along the first direction. A gate dielectric layer 211 and a gate conductive material may be formed in the gate trenches 212 so as to form the gate electrode. Thereafter, source contact openings 112 may be formed in the main surface 110, e.g. by using photolithographical and etching methods. For example, the source contact openings 112 may be formed so as to be adjacent to the gate trenches 212.

FIG. 6B illustrates a horizontal cross-sectional view of the semiconductor substrate after forming the gate trenches 212 and the source contact openings 112. A first sidewall 112a of the source contact openings 112 extends along the first direction, whereas the second sidewall 112b extends along the second direction. A first tilted ion implantation step (P1) is performed, as is also illustrated in FIG. 6A. This ion implantation step is performed so as to introduce dopants of the first conductivity type through the second sidewall 112b into the semiconductor substrate. This ion implantation step may be performed as a “dual” ion implantation step so that the two first sidewalls 112b, each extending along the second direction are doped and facing each other. Thereafter, the substrate is rotated by 90° and a further ion implantation step (P2) is performed. As is illustrated in FIG. 6C, this ion implantation step is performed as a tilted ion implantation step so as to introduce dopants of the first conductivity type through the first sidewalls 112a of the source contact openings 112 into the semiconductor body 100. This ion implantation step is performed with dopants of the second conductivity type so as to form the body contact portions 225. FIG. 6B illustrates the substrate after performing the respective ion implantation step. Also the second ion implantation step is performed as a “dual” mode ion implantation step by which opposing sidewalls 112a of the source contact openings 112 are doped.

As is to be clearly understood, the ion implantation step P2 illustrated in FIG. 6C may be performed before or after performing the ion implantation step illustrated in FIG. 6A. Further, the ion implantation step of FIG. 6C may also comprise a ion implantation step without a tilt angle so as to dope the bottom portion of the source contact openings 112. Further, annealing steps may be performed so as to diffuse the dopants in the substrate material. As is to be understood, the annealing step may be performed after finishing each of the ion implantation steps. According to a further embodiment, first, the ion implantation steps may be performed, followed by the annealing step. By reversing the doping type for performing the ion implantation steps illustrated in FIGS. 6A and 6C, the transistors illustrated in FIGS. 2A to 2C may be manufactured. Further, in this case, the position of the source contact openings 112 has to be shifted with respect to the position of the source contact openings 112 illustrated in FIG. 1A.

The embodiment illustrated in FIGS. 6A to 6C specifically uses an anisotropic doping method. According to further embodiments, isotropic doping methods may be used in combination with a suitable method for patterning a doping mask. Examples of the isotropic doping methods comprise plasma assisted doping methods (PLAD), thermal doping processes from the gas phase and deposition of a doped glass such as boron silicate glass (BSG) or phosphorous silicate glass (PSG). Forming a doping mask may comprise forming a silicon oxide layer on the sidewalls of the source contact opening 112 or the source contact groove 114. Thereafter, portions of the silicon oxide layer may be damaged, for example, by doping with Ar ions. The etching rate in diluted hydrofluoric acid may be increased in the damaged portions with respect to the non-damaged portions. Using a correspondingly patterned mask, an isotropic doping method may be performed, resulting in differently doped semiconductor portions at the sidewalls.

For manufacturing the semiconductor device illustrated in FIGS. 3A to 3C, the doping process as illustrated in FIG. 6A may be performed, wherein the sidewalls 128a of the second source contacts 128 are masked when performing an ion implantation process for doping the source regions 201. Further, when doping the body contact portions 225, the sidewalls 127a of the first source contacts 127 are masked.

For manufacturing the semiconductor device illustrated in FIGS. 4A to 4C, a doping process as illustrated in FIG. 6A may be performed, wherein sections of the sidewall 114b of the source contact groove are appropriately masked. For example, sections of the sidewalls may be masked by a photoresist material. According to a further embodiment, a hard mask material may be filled into the source contact groove 114, followed by patterning the hard mask material so as to form an ion implantation mask.

The semiconductor device may be further processed using generally known processing methods.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A semiconductor device comprising a transistor in a semiconductor body having a main surface, the transistor comprising:
a source region;
a drain region;
a body region;
a drift zone;
a gate electrode at the body region, the body region and the drift zone being disposed along a first direction between the source region and the drain region, the first direction being parallel to the main surface, the gate electrode being disposed in a trench extending in the first direction,
a source contact electrically connected to the source region and to a source terminal, the source contact being disposed in a source contact opening in the main surface, and
a body contact portion electrically connected to the source terminal and to the body region, the body contact portion vertically overlapping with the source region.

2. The semiconductor device according to claim 1, wherein the body contact portion vertically extends along the source contact opening.

3. The semiconductor device according to claim 1, wherein the source region vertically extends along the source contact opening.

4. The semiconductor device according to claim 1, wherein the source contact opening and the source region are arranged along the along the first direction.

5. The semiconductor device according to claim 4, wherein a position of the source contact opening is aligned with the position of the gate electrode along a second direction different from the first direction.

6. The semiconductor device according to claim 1, wherein the source contact opening and the source region are arranged along a second direction parallel to the main surface, the second direction being different from the first direction.

7. The semiconductor device according to claim 6, wherein a position of the source contact opening is shifted along the second direction with respect to the position of the gate electrode.

8. The semiconductor device according to claim 1, wherein a portion of the body contact portion is disposed adjacent to the source contact opening.

9. The semiconductor device according to claim 1, wherein the source region and the drain region are of a first conductivity type, and the body contact portion is of a second conductivity type, different from the first conductivity type.

10. A semiconductor device comprising an array of transistors in a semiconductor body having a main surface, each of the transistors comprising:
a source region;
a drain region;
a body region;
a drift zone;
a gate electrode at the body region, the body region and the drift zone being disposed along a first direction between the source region and the drain region, the first direction being parallel to the main surface, the gate electrode being disposed in trenches extending in the first direction,
a source contact electrically connected to the source region and to a source terminal, and
a body contact portion electrically connected to the source contact and to the body region, the body contact portion being disposed at a sidewall of the source contact.

11. The semiconductor device according to claim 10, wherein source contacts of adjacent transistors are disposed in a source contact groove in the main surface, the source contact groove extending in a second direction parallel to the main surface, the second direction being different from the first direction, the body contact portion being disposed at a sidewall of the source contact groove.

12. The semiconductor device according to claim 11, wherein the source regions and the body contact portions are disposed at sidewalls of the source contact groove.

13. The semiconductor device according to claim 10, wherein the source contacts of adjacent transistors are spatially separated from each other.

14. The semiconductor device according to claim 10, wherein the source region and the drain region are of a first conductivity type, and the body contact region is of a second conductivity type.

15. A semiconductor device comprising an array of transistors in a semiconductor body having a main surface, each of the transistors comprising:
a source region;
a drain region;
a body region;
a drift zone;
a gate electrode at the body region, the body region and the drift zone being disposed along a first direction between the source region and the drain region, the first direction being parallel to the main surface, the gate electrode being disposed in trenches extending in the first direction,
a first source contact electrically connected to the source region and to a source terminal,
a second source contact disposed in a second source contact opening in the semiconductor body, and
a body contact portion electrically connected to the second source contact and to the body region, the body contact portion being disposed at a sidewall of the second source contact opening.

16. The semiconductor device according to claim 15, wherein first source contacts and second source contacts of the array of transistors are alternatingly disposed along a second direction perpendicular to the first direction.

17. The semiconductor device according to claim 15, wherein a distance between the body contact portion and the drain region is smaller than the distance between the source region and the drain region.
